(19) United States
(12) Patent Application Publication
(10) Pub. No.: US 2026/0073087 A1
(43) Pub. Date: Mar. 12, 2026

(54) INTELLIGENT DESIGN METHOD AND DEVICE FOR THICK-PLATE JOINT OF LONGITUDINAL AND CROSS MEMBERS OF ALUMINUM ALLOY VEHICLE FRAME

(71) Applicant: Jilin University, Changchun City (CN)

(72) Inventors: Dengfeng WANG, Changchun City (CN); Hongli CHEN, Changchun City (CN); Shang ZHANG, Changchun City (CN); Zifeng ZHANG, Changchun City (CN); Yenan NI, Changchun City (CN); Zihao MENG, Changchun City (CN); Fengmin LIAN, Changchun City (CN); Jialin DONG, Changchun City (CN)

(73) Assignee: Jilin University, Changchun City (CN)

(21) Appl. No.: 19/313,223

(22) Filed: Aug. 28, 2025

(30) Foreign Application Priority Data
Sep. 9, 2024 (CN) 202411252895.8

(51) Int. Cl. G06F 30/15

(52) U.S. Cl. CPC G06F 30/15

(57) ABSTRACT

Provided are an intelligent design method and device for a thick-plate joint of longitudinal and cross members of an aluminum alloy vehicle frame. The intelligent design method includes: establishing a finite element model of a vehicle frame, analyzing static performance and fatigue performance of the vehicle frame under bending and torsion conditions, and selecting a connection joint of longitudinal and cross members with weak static performance and fatigue performance on the vehicle frame as a submodel; with connection parameters of the submodel as design variables, obtaining, by simulation, sets of training samples and a corresponding target response data set; establishing forward and inverse mapping relationships between design variables of a connection joint of longitudinal and cross members and target responses; and then on the basis of fully training the neural network model, obtaining an optimal layout scheme of connection joint fasteners of longitudinal and cross members by prediction and optimization.

### CROSS REFERENCE TO RELATED APPLICATION

This patent application claims the benefit and priority of Chinese Patent Application No. 202411252895.8, filed with the China National Intellectual Property Administration on Sep. 9, 2024, the disclosure of which is incorporated by reference herein in its entirety as part of the present application.

### TECHNICAL FIELD

The present disclosure belongs to the technical field of automobile manufacturing, and in particular, to an intelligent design method and device for a thick-plate joint of longitudinal and cross members of an aluminum alloy vehicle frame.

### BACKGROUND

A vehicle frame, as a primary load-bearing component for a cab, a powertrain, a spare tire, and a container, has its reliability directly tied not only to the service life of an entire vehicle but also closely related to ride comfort and driving smoothness. Traditional commercial vehicle frames are predominantly made of high-strength steel, with steel bolts and rivets used as fasteners for connecting cross and longitudinal members. However, faced with increasing constraints on energy conservation, emission reduction, and consumption reduction, steel vehicle frames have limited potential for further weight reduction from the perspectives of both structure and manufacturing process. Consequently, the development of aluminum vehicle frames has become a critical priority. Nevertheless, the connection structures of aluminum vehicle frames still largely emulate those of steel vehicle frames, presenting two major challenges: immature connection solutions and insufficient fatigue performance. This urgently necessitates parameter optimization in the design of the connection structures of aluminum vehicle frames.

As a key research object for commercial vehicle lightweighting, aluminum alloy vehicle frames have seen structural innovations by some inventors. Currently, most patents related to aluminum alloy vehicle frames of commercial vehicles concentrate on structural design aspects, while few address optimization designs for thick-plate connection structures of cross and longitudinal members of vehicle frames. For example, Chinese Patent Application No. 2023110884898 proposes a vehicle frame, a chassis, and a vehicle, where a cross member is provided to connect two longitudinal members, and respective connection structures are provided on the longitudinal and cross members to connect a suspension with no need for a subframe. Chinese Patent Application No. 2023112223989 proposes a reinforced connection structure for a front subframe, where a reinforcing plate is designed for connection to provide firmer support of the subframe, thereby improving vehicle safety and comfort. However, to guarantee that connection mechanisms for longitudinal and cross members of aluminum alloy vehicle frames meet the performance requirements of the vehicle frames, innovative designs need to be made in terms of layout and arrangement of connecting fasteners of aluminum vehicle frames on the basis of steel vehicle frame connection structures so as to maximize the performance of aluminum vehicle frame connection structures.

### SUMMARY

To solve the above technical problems, the present disclosure provides an intelligent design method and device for a thick-plate joint of longitudinal and cross members of an aluminum alloy vehicle frame. The present disclosure can accurately determine a material selected for, a number of, sizes of, and positions of fasteners of a connection structure of longitudinal and cross members, achieve best matching between the fasteners and plate properties, and reduce the concentration of stress at the connection of the longitudinal and cross members, playing a promoting role in improving the fatigue performance of an aluminum alloy vehicle frame and facilitating further use of the aluminum alloy vehicle frame.

The present disclosure provides the following technical solutions.

An intelligent design method for a thick-plate joint of longitudinal and cross members of an aluminum alloy vehicle frame includes the following steps:
S1, establishing an overall finite element model of a vehicle frame;
S2, analyzing static performance of the vehicle frame based on the overall finite element model to obtain strength and rigidity response information of the vehicle frame;
S3, analyzing fatigue performance of the vehicle frame with a virtual prototype model of an entire vehicle to obtain a fatigue life of the vehicle frame;
S4, selecting a joint of longitudinal and cross members with the weakest static performance and fatigue performance of the vehicle frame and establishing a joint finite element submodel;
S5, establishing a joint design variable-performance response variable data set based on the joint finite element submodel;
S6, training a neural network model with the joint design variable-performance response variable data set; and
S7, outputting performance response variables corresponding to a plurality of joint design variable schemes using the trained neural network model, and selecting an optimal design scheme from the plurality of joint design variable schemes based on a forward optimization model; and given a target performance response variable, selecting an optimal design scheme from the plurality of joint design variable schemes based on an inverse optimization model,
where design variables include a nominal diameter d, a material type m, a number n, an edge distance e, and a spacing s of fasteners, and thicknesses t1 and t2 of connecting plates for the longitudinal and cross members; and the performance response variables include a fatigue life N, a mass M, a maximum stress, and a maximum deformation amount of a joint.

Further, in step S2, corresponding boundary conditions are applied under a bending condition and a torsion condition of the vehicle frame, and bending and torsion static performance of the vehicle frame is analyzed to obtain the strength and rigidity response information of the vehicle frame, where under the bending condition, translational degrees of freedom of a connection point of a rear suspension of the vehicle frame and the vehicle frame in a transverse direction, a longitudinal direction and a vertical direction are constrained, and a translational degree of freedom of a connection point of a front suspension and the vehicle frame in the vertical direction is constrained; and under the torsion condition, all translational and rotational degrees of freedom of connection points of the front and rear suspensions and the vehicle frame on a single side are constrained.

Further, in step S3, a load time history of a connection point of the vehicle frame and an assembly under typical conditions is extracted using the virtual prototype model of the entire vehicle, a vehicle frame load spectrum is compiled by a rain flow counting method, and the fatigue life of the vehicle frame is calculated by a nominal stress method and a cumulative fatigue damage theory.

Further, in step S5, suitable initial values and value ranges are set for the design variables in accordance with an actual connection of the longitudinal and cross members, and then a design variable test space is established using an optimal Latin hypercube sampling method to obtain a plurality of sets of sample data for establishing a data set.

Further, in step S6, the neural network model is a real-valued non-volume preserving (Real NVP) neural network model including an input layer, an output layer, and a plurality of hidden layers between the input layer and the output layer, each including a plurality of processing units correlated to one another; the input layer is configured to input design variables of the joint of the longitudinal and cross members, and the output layer is configured to output corresponding performance response variables of the joint of the longitudinal and cross members.

Further, an exponential linear unit (ELU) activation function is used as a neuron for the hidden layers of the neural network model, a stochastic gradient descent method is used as an optimizer, and a mean square error function is used as a loss function.

Further, in step S7, the forward optimization model is expressed as:

$$\begin{matrix}find DV = {( d , {t}_{1} , {t}_{2} , e , s , n , m )}^{T} \\ \{ \begin{matrix}max \{ N ( x ) \} \& min \{ M ( x ) \} \\ s . t . \{ \begin{matrix}S \leq {S}_{y} \\ K \geq {K}_{0} \\ e \geq {e}_{0} \\ s \geq {s}_{0}\end{matrix}\end{matrix}\end{matrix}$$

where find DV=(d,t₁,t₂,e,s,n,m)^{T} represents optimal design variables to be obtained, and max{N(x)}&min{M(x)} represents an optimization objective of maximizing the fatigue life N and minimizing the mass M, with constraint conditions including: a maximum stress S of a connection joint of longitudinal and cross members being no greater than an allowable stress S_{y} for a material, rigidity K being no less than a set minimum rigidity value K₀, the edge distance e of fasteners being no less than a minimum edge distance e₀, and the spacing s being no less than a minimum spacing s₀.

Further, in step S7, the inverse optimization model is expressed as:

$$\begin{matrix}find DV = {( d , {t}_{1} , {t}_{2} , e , s , n , m )}^{T} \\ \{ \begin{matrix}min \{ Q ( x ) \} \\ s . t . \{ \begin{matrix}S \leq {S}_{y} \\ K \geq {K}_{0} \\ e \geq {e}_{0} \\ s \geq {s}_{0}\end{matrix}\end{matrix}\end{matrix}$$

where find DV=(d,t₁,t₂,e,s,n,m)^{T} represents optimal design variables to be obtained, Q(x) represents a difference between the target performance response variable and a performance response variable output by the neural network model, and min{Q(x)} represents an optimization objective of minimizing Q(x), with constraint conditions including: a maximum stress S of a connection joint of longitudinal and cross members being no greater than an allowable stress S_{y} for a material, rigidity K being no less than a set minimum rigidity value K₀, the edge distance e of fasteners being no less than a minimum edge distance e₀, and the spacing s being no less than a minimum spacing s₀.

An intelligent design device for a thick-plate joint of longitudinal and cross members of an aluminum alloy vehicle frame based on the intelligent design method described above includes:
an entire-vehicle finite element model establishment module configured to establish an overall finite element model of a vehicle frame;
a static performance analysis module configured to obtain strength and rigidity response information of the vehicle frame;
a fatigue performance analysis module configured to obtain a fatigue life of the vehicle frame;
a joint selection and finite element submodel establishment module configured to select a joint of longitudinal and cross members with the weakest static performance and fatigue performance of the vehicle frame and establish a joint finite element submodel;
a data set establishment module configured to obtain sample data using the joint finite element submodel and establish a joint design variable-performance response variable data set;
a neural network model training and utilization module configured to train a neural network model with the joint design variable-performance response variable data set established by the data set establishment module, the neural network model being configured to predict and output corresponding performance response variables based on input joint design variables;
a forward design module configured to output performance response variables corresponding to a plurality of joint design variable schemes using a trained neural network model, and select an optimal design scheme from the plurality of joint design variable schemes based on a forward optimization model; and
an inverse design module configured to output performance response variables corresponding to a plurality of joint design variable schemes using a trained neural network model, and select an optimal design scheme from the plurality of joint design variable schemes based on an inverse optimization model.

Compared with the prior art, the present disclosure has at least the following beneficial effects.
1. According to the present disclosure, based on the optimization theory, optimization is made to the material, the sizes, and the layout and arrangement of fasteners of the thick-plate connection structure for the longitudinal and cross members of the aluminum alloy vehicle frame. The problem of surplus or substandard static performance and fatigue life of the joint in the traditional method which relies on the engineering experience and benchmarking design is solved.
2. According to the present disclosure, bidirectional mapping relationships between input variables of a thick-plate connection joint of longitudinal and cross members of an aluminum alloy vehicle frame and target responses are established. Not only can the target responses be predicted based on the input variables, but also a joint structure design scheme can be ascertained on the premise of the known target responses. Rapid intelligent design of the connection parameters of the thick-plate connection joint of the longitudinal and cross members is achieved. The design efficiency is improved and the development cycle is shortened.
3. The present disclosure provides an intelligent design scheme for a thick-plate joint of longitudinal and cross members of an aluminum alloy vehicle frame that has good nonlinear generalization capability and high solving accuracy. When the structure of an optimization object has a great change, the intelligent optimization design scheme still can offer satisfactory calculation results.

### BRIEF DESCRIPTION OF THE DRAWINGS

The accompanying drawings are intended to provide a further understanding of the present disclosure, constitute a part of the specification, and are intended to explain the present disclosure together with the embodiments of the present disclosure, rather than to constitute a limitation to the present disclosure.

FIG. 1 is a schematic diagram of a thick-plate connection of longitudinal and cross members of a vehicle frame provided by an embodiment of the present disclosure;

FIG. 2 is a flowchart of an intelligent design method for a thick-plate joint of longitudinal and cross members provided by an embodiment of the present disclosure;

FIG. 3 is a schematic diagram of a finite element model of a vehicle frame and a connection joint submodel of longitudinal and cross members provided by an embodiment of the present disclosure;

FIG. 4 is a schematic diagram of a fatigue life prediction output by a model provided by an embodiment of the present disclosure; and

FIG. 5 is a schematic diagram of a fastener spacing prediction output by a model provided by an embodiment of the present disclosure.

### DETAILED DESCRIPTION OF THE EMBODIMENTS

To make the objective, technical solutions, and advantages of the embodiments of the present disclosure clearer, the technical solutions in the embodiments of the present disclosure will be described below clearly and completely with reference to the accompanying drawings in the embodiments of the present disclosure. Apparently, the described embodiments are some rather than all of the embodiments of the present disclosure. All other embodiments derived from the embodiments of the present disclosure by those skilled in the art without creative efforts shall fall within the protection scope of the present disclosure.

### Embodiment 1

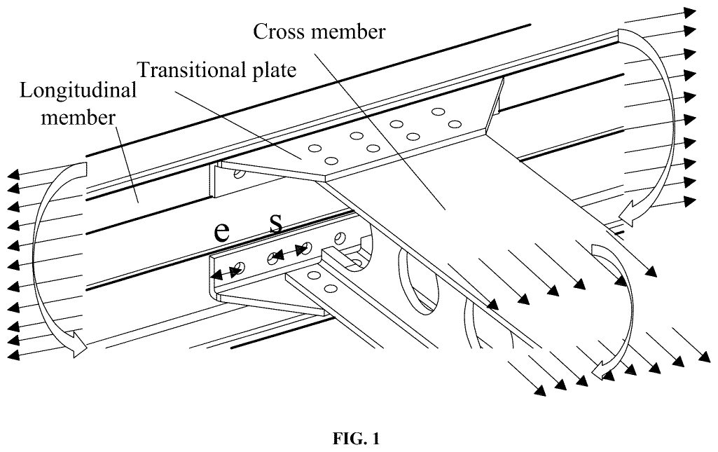

As shown in FIG. 1, a longitudinal member and a cross member of an aluminum alloy vehicle frame of an electric cargo truck typically have a thickness of 6-18 mm, and the connection manners adopted usually are bolting and press riveting, where the longitudinal member of the vehicle frame is bolted to a transitional plate, and the cross member of the vehicle frame is press-riveted to the transitional plate.

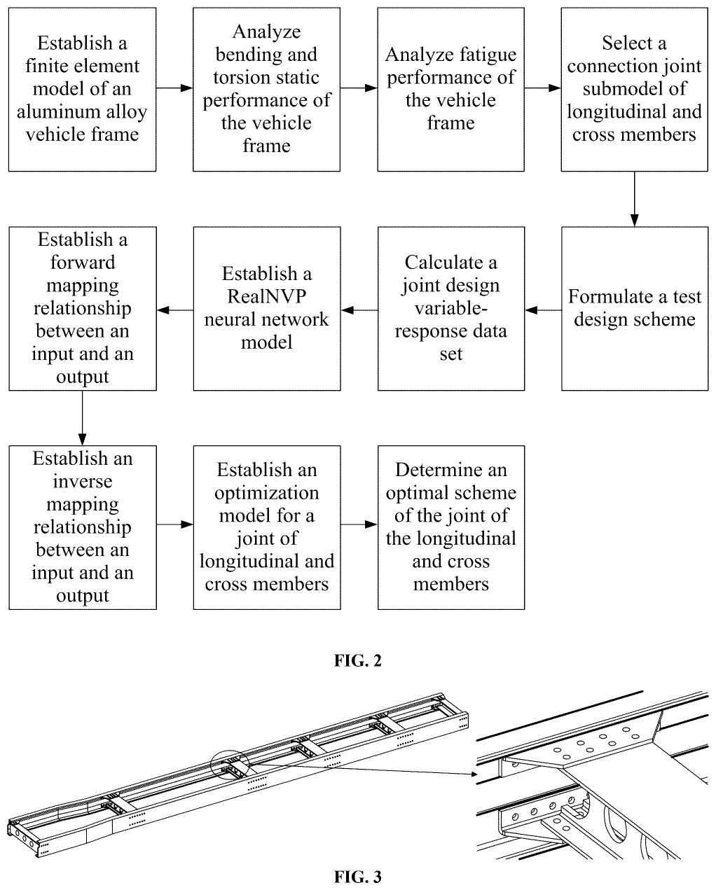

In order to reduce the concentration of stress at the connection of the longitudinal and cross members and improve the fatigue performance of the aluminum alloy vehicle frame, the present embodiment provides an intelligent design method for a thick-plate joint of longitudinal and cross members of an aluminum alloy vehicle frame, and its major steps are as shown in FIG. 2 and described below.

An overall finite element model of an aluminum alloy vehicle frame is established, as shown in FIG. 3.

A load 1.5 times the full load of the vehicle frame is used as a static load of the vehicle frame. Corresponding boundary conditions are applied under a bending condition and a torsion condition of the vehicle frame, and bending and torsion static performance of the vehicle frame is analyzed to obtain strength and rigidity response information of the vehicle frame. Under the bending condition, translational degrees of freedom of a connection point of a rear suspension of the vehicle frame and the vehicle frame in a transverse direction, a longitudinal direction and a vertical direction are constrained, and a translational degree of freedom of a connection point of a front suspension and the vehicle frame in the vertical direction is constrained; and under the torsion condition, all translational and rotational degrees of freedom of connection points of the front and rear suspensions and the vehicle frame on a single side are constrained.

The fatigue performance of the aluminum alloy vehicle frame is analyzed. A load time history of a connection point of the vehicle frame and an assembly under typical conditions is extracted using the virtual prototype model of the entire vehicle, a vehicle frame load spectrum is compiled by a rain flow counting method, and the fatigue life of the vehicle frame is calculated by a nominal stress method and a cumulative fatigue damage theory. The rain flow counting method was proposed in the 1950s by two British engineers. This counting method primarily serves to simplify a measured load history into a series of load cycles for fatigue life estimation and the compilation of fatigue test load spectra. The nominal stress method is a method for calculating the fatigue life of a material or a component. Using stress and a stress concentration factor as parameters, this method characterizes the material fatigue behaviors with an S-N curve of the material. Based on the cumulative fatigue damage theory, this method estimates the fatigue life by analyzing the component's nominal stress and stress concentration factor in conjunction with the S-N curve. Specifically, the nominal stress method employs the rain flow method to extract mutually independent and uncorrelated stress cycles, and estimates the fatigue life of the structure by combining the material's S-N curve with the linear cumulative damage theory. Since these methods are prior art, they will not be described here redundantly in the present embodiment.

Based on the results of the above static performance analysis and the fatigue performance analysis, a joint of longitudinal and cross members with the weakest static performance and fatigue performance of the aluminum alloy vehicle frame is selected, static and fatigue loads of the joint are extracted, and a joint finite element submodel is established. The established joint finite element submodel is utilized to analyze the influences of connection parameters such as the sizes, the spacing, and the edge distance of bolts and rivets on the static performance and the fatigue performance of the joint. Specifically,

TABLE 1
Initial Design Variables and Variation
Ranges of Connection Joint Submodel

| | | Design | Variable Range | Initial Value |
|---|---|---|---|---|
| SN | Name | Variable | (mm) | (mm) |
| 1 | Size of fastener | d | d ∈ | 14 |
| | | | (8, 10, 12, 14, 16) | |
| 2 | Thickness of | t1 | t1 ∈ [8:18] | 12 |
| | connecting plate for | | | |
| | cross member | | | |
| 3 | Thickness of | t2 | t2 ∈ [8:18] | 12 |
| | connecting plate for | | | |
| | longitudinal member | | | |
| 4 | Edge distance of | e | e ∈ [6:16] | 8 |
| | fasteners | | | |
| 5 | Spacing of fasteners | s | t ∈ [6:16] | 8 |
| 6 | Number of fasteners | n | n ∈ | 4 |
| | | | (2, 4, 6, 8, 10) | |
| 7 | Material of fastener | m | Al6061, 40Cr, . . . , | 40Cr |
| | | | 45# | |

Seven joint design variables are selected, including three discrete design variables (i.e., nominal diameter d, material type m, and number n) and four continuous design variables (i.e., thickness t1 of the connecting plate for the longitudinal member, thickness t2 of the connecting plate for the cross member cross, edge distance e of connecting fasteners, and spacing s) of the connecting fasteners (bolts and rivets). Suitable initial values and value ranges (see table 1) are set for the design variables in accordance with an actual connection of the longitudinal and cross members, and then a design variable test space is established using an optimal Latin hypercube sampling method to obtain a total of 100 sets of test sample data. By simulating calculation, response values of each sample are obtained, namely the corresponding fatigue life, mass, maximum stress, and maximum deformation amount of the joint for each value of each joint design variable. As a result, a design variable-response data set is formed. The optimal Latin hypercube sampling method is an advanced Latin hypercube sampling technique designed to enhance the efficiency and accuracy of sampling through optimization of spatial positions of sample points. Compared with conventional Latin hypercube sampling, the optimal Latin hypercube sampling can better handle high correlations among input variables while producing more rational samples, thereby improving the simulation accuracy. Since these methods are prior art, they will not be described here redundantly in the present embodiment.

A forward mapping relationship between design variables and target responses is established. A Real NVP neural network model is established, which includes an input layer, an output layer, and a plurality of hidden layers between the input layer and the output layer, each including a plurality of processing units correlated to one another. The input layer is configured to input design variables of the joint of the longitudinal and cross members (various sets of connection parameters of the joint), and the output layer is configured to output corresponding fatigue life, mass, maximum stress, and maximum deformation amount of the joint of the longitudinal and cross members. A neuron in the hidden layer performs nonlinear conversion on the input data through an exponential linear unit (ELU) activation function. A learning rate and a number of network nodes are set. A stochastic gradient descent (SGD) method is used as an optimizer, and a mean square error (MSE) function is used as a loss function. The model is trained with the design variable-response data set established above, and the training effect is optimized and assessed. 80% of data of the resulting simulation data set is used as a training data set for determining the parameters of the neural network model, and 20% of data of the simulation data set is used for checking the prediction accuracy of the model.

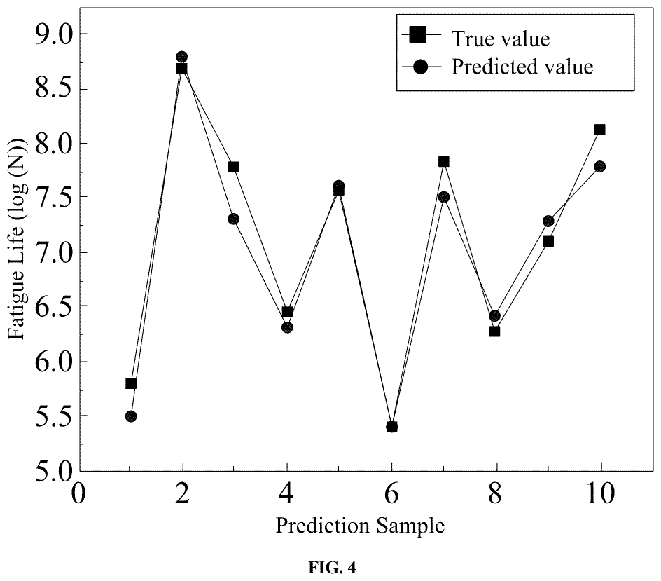

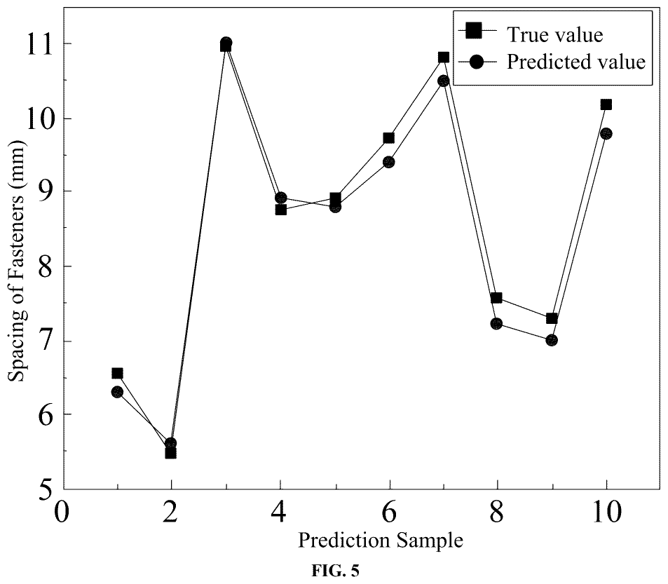

An inverse mapping relationship between target responses (output) and design variables (input) is established. On the basis of the trained forward model, the input parameters are optimized by a backpropagation algorithm such that the model output approaches a predetermined objective. The specific approach is as follows: on the basis of the known forward mapping relationship between design variables (input) and target responses (output), a set of expected target response values is given. Respective response variables can be obtained through the forward model for different design variables. An objective function Q(x) is defined, representing differences between the response variables corresponding to the design variables and the expected target responses (the objective function may also be construed as a difference between an output of the forward model and expected performance). Partial derivatives (i.e., gradients) of the parameters of each layer in the neural network model to the loss function are calculated by the SGD backpropagation algorithm. The gradient information of the forward model is transferred back to the input layer. A gradient descent optimization algorithm is employed to adjust the input variables from the gradient information obtained from backpropagation so as to minimize the objective function, making the output of the forward model continuously approach the expected performance. Thus, the input parameters are updated, thereby achieving the purpose of predicting the input variable information with the target responses. The predicted results and the test results are as shown in FIG. 4 and FIG. 5.

The response variables can be predicted accurately on the premise of the known design variables as long as the forward mapping relationship is known. In the inverse design, design variables are predicted with response variables. This requires the response variables in one-to-one correspondence with the design variables to be obtained through the forward mapping relationship. The response variables obtained one by one are compared with the expected target responses. The design variables corresponding to a set of response variables closest to the target responses are the final results found.

A parameter optimization model for a thick-plate connection joint of longitudinal and cross members of an aluminum alloy vehicle frame is established. A forward optimization objective is defined as maximizing the fatigue life N and minimizing the mass M of the connection joint of the longitudinal and cross members, as shown in formula (1). Constraint conditions includes: a maximum stress S of the connection joint of the longitudinal and cross members being no greater than an allowable stress S_{y} for a material, rigidity K being greater than a set minimum rigidity value K₀, a certain assembly space being retained when mounting fasteners (with an edge distance e being no less than a minimum edge distance e₀), and an arrangement of the connecting fasteners meeting a symmetric relationship (with a spacing s being no less than a minimum spacing s₀).

$$\begin{matrix}find DV = {( d , {t}_{1} , {t}_{2} , e , s , n , m )}^{T} \\ \{ \begin{matrix}max \{ N ( x ) \} \& min \{ M ( x ) \} \\ s . t . \{ \begin{matrix}S \leq {S}_{y} \\ K \geq {K}_{0} \\ e \geq {e}_{0} \\ s \geq {s}_{0}\end{matrix}\end{matrix}\end{matrix} \qquad ( 1 )$$

$$\begin{matrix}find DV = {( d , {t}_{1} , {t}_{2} , e , s , n , m )}^{T} \\ \{ \begin{matrix}min \{ Q ( x ) \} \\ s . t . \{ \begin{matrix}S \leq {S}_{y} \\ K \geq {K}_{0} \\ e \geq {e}_{0} \\ s \geq {s}_{0}\end{matrix}\end{matrix}\end{matrix} \qquad ( 2 )$$

An optimal design scheme of the connection joint of the longitudinal and cross members is determined. In the forward design, the formula (1) is used as the optimization model. A non-dominated sorting genetic algorithm III (NSGAIII) is utilized to obtain, through optimization of the output of the forward neural network model, the best design scheme (design variables) for the connection structure of the longitudinal and cross members with regard to the material, sizes, and layout and arrangement of fasteners, and verify the effectiveness of the optimization scheme. In the inverse design, on the basis of the known forward neural network model, formula (2) is used as the optimization model. The gradient descent optimization algorithm is utilized to output a design of the connection structure of the longitudinal and cross members with regard to the material, sizes, and layout and arrangement of fasteners on the premise of the given expected target performance.

In this way, bidirectional mapping relationships between the input variables of the thick-plate connection joint of the longitudinal and cross members of the aluminum alloy vehicle frame and target responses are established. Not only can the target responses be predicted based on the input variables, but also a joint structure design scheme can be ascertained on the premise of the known target responses. Rapid intelligent design of the connection parameters of the thick-plate connection joint of the longitudinal and cross members is achieved. The design efficiency is improved and the development cycle is shortened.

### Embodiment 2

Based on the intelligent design method for a thick-plate joint of longitudinal and cross members of an aluminum alloy vehicle frame provided by Embodiment 1, the present embodiment provides an intelligent design device for a thick-plate joint of longitudinal and cross members of an aluminum alloy vehicle frame, which mainly includes the following modules:
an entire-vehicle finite element model establishment module configured to establish an overall finite element model of a vehicle frame;
a static performance analysis module configured to obtain strength and rigidity response information of the vehicle frame;
a fatigue performance analysis module configured to obtain a fatigue life of the vehicle frame;
a joint selection and finite element submodel establishment module configured to select a joint of longitudinal and cross members with the weakest static performance and fatigue performance of the vehicle frame and establish a joint finite element submodel;
a data set establishment module configured to obtain sample data using the joint finite element submodel and establish a joint design variable-performance response variable data set;
a neural network model training and utilization module configured to train a neural network model with the joint design variable-performance response variable data set established by the data set establishment module, the neural network model being configured to predict and output corresponding performance response variables based on input joint design variables;
a forward design module configured to output performance response variables corresponding to a plurality of joint design variable schemes using a trained neural network model, and select an optimal design scheme from the plurality of joint design variable schemes based on a forward optimization model; and
an inverse design module configured to output performance response variables corresponding to a plurality of joint design variable schemes using a trained neural network model, and select an optimal design scheme from the plurality of joint design variable schemes based on an inverse optimization model.

To sum up, the finite element model of the aluminum alloy vehicle frame is established to analyze the static performance and fatigue performance of the vehicle frame under the bending and torsion conditions, and the connection joint of the longitudinal and cross members with weak static performance and fatigue performance on the vehicle frame is selected as the submodel. The static and fatigue loads of the joint submodel are extracted; the finite element model of the connection joint is established; the connection parameters of the submodel are used as the design variables; the test design space is established using the optimal Latin hypercube sampling algorithm; and by simulation calculation, the sets of test samples and the corresponding target response data set are obtained. Forward and inverse mapping relationships between the design variables (input) of the connection joint of the longitudinal and cross members and the target responses (output) are established by deep machine learning using the Real NVP neural network model; and then on the basis of fully training the neural network model, according to the technical requirements on the connection performance of the longitudinal and cross members of the vehicle frame, the NSGAIII is utilized to obtain the best layout and arrangement scheme of the connection joint fasteners of the longitudinal and cross members by optimization using the neural network model. Thus, the objective of determining the connection design scheme of the longitudinal and cross members of the vehicle frame according to the connection performance response requirements of the vehicle frame is efficiently achieved with the intelligent design method.

Finally, it should be noted that the above embodiments are merely provided to explain the technical solutions of the present disclosure, rather than limit the present disclosure. Under the idea of the present disclosure, the above embodiments or technical features in different embodiments may also be combined, the steps may be implemented in any order, and there are many variations in different aspects of the present disclosure described above, which are not provided in detail for the sake of brevity. Although the present disclosure is described in detail with reference to the above embodiments, a person of ordinary skill in the art should understand that they can still modify the technical solutions described in the above embodiments or make equivalent substitutions for some technical features therein, and these modifications or substitutions do not make the essence of corresponding technical solutions depart from the scope of the technical solutions of the embodiments of the present disclosure.

What is claimed is:

1. An intelligent design method for a thick-plate joint of longitudinal and cross members of an aluminum alloy vehicle frame, comprising the following steps:
S1, establishing an overall finite element model of a vehicle frame;
S2, analyzing static performance of the vehicle frame based on the overall finite element model to obtain strength and rigidity response information of the vehicle frame;
S3, analyzing fatigue performance of the vehicle frame with a virtual prototype model of an entire vehicle to obtain a fatigue life of the vehicle frame;
S4, selecting a joint of longitudinal and cross members with the weakest static performance and fatigue performance of the vehicle frame and establishing a joint finite element submodel;
S5, establishing a joint design variable-performance response variable data set based on the joint finite element submodel;
S6, training a neural network model with the joint design variable-performance response variable data set; and
S7, outputting performance response variables corresponding to a plurality of joint design variable schemes using the trained neural network model, and selecting an optimal design scheme from the plurality of joint design variable schemes based on a forward optimization model; and given a target performance response variable, selecting an optimal design scheme from the plurality of joint design variable schemes based on an inverse optimization model,
wherein design variables comprise a nominal diameter d, a material type m, a number n, an edge distance e, and a spacing s of fasteners, and thicknesses t1 and t2 of connecting plates for the longitudinal and cross members; and the performance response variables comprise a fatigue life N, a mass M, a maximum stress, and a maximum deformation amount of a joint.

2. The intelligent design method for a thick-plate joint of longitudinal and cross members of an aluminum alloy vehicle frame according to claim 1, wherein in step S2, corresponding boundary conditions are applied under a bending condition and a torsion condition of the vehicle frame, and bending and torsion static performance of the vehicle frame is analyzed to obtain the strength and rigidity response information of the vehicle frame, wherein under the bending condition, translational degrees of freedom of a connection point of a rear suspension of the vehicle frame and the vehicle frame in a transverse direction, a longitudinal direction and a vertical direction are constrained, and a translational degree of freedom of a connection point of a front suspension and the vehicle frame in the vertical direction is constrained; and under the torsion condition, all translational and rotational degrees of freedom of connection points of the front and rear suspensions and the vehicle frame on a single side are constrained.

3. The intelligent design method for a thick-plate joint of longitudinal and cross members of an aluminum alloy vehicle frame according to claim 1, wherein in step S3, a load time history of a connection point of the vehicle frame and an assembly under typical conditions is extracted using the virtual prototype model of the entire vehicle, a vehicle frame load spectrum is compiled by a rain flow counting method, and the fatigue life of the vehicle frame is calculated by a nominal stress method and a cumulative fatigue damage theory.

4. The intelligent design method for a thick-plate joint of longitudinal and cross members of an aluminum alloy vehicle frame according to claim 1, wherein in step S5, suitable initial values and value ranges are set for the design variables in accordance with an actual connection of the longitudinal and cross members, and then a design variable test space is established using an optimal Latin hypercube sampling method to obtain a plurality of sets of sample data for establishing a data set.

5. The intelligent design method for a thick-plate joint of longitudinal and cross members of an aluminum alloy vehicle frame according to claim 1, wherein in step S6, the neural network model is a real-valued non-volume preserving (Real NVP) neural network model comprising an input layer, an output layer, and a plurality of hidden layers between the input layer and the output layer, each comprising a plurality of processing units correlated to one another; the input layer is configured to input design variables of the joint of the longitudinal and cross members, and the output layer is configured to output corresponding performance response variables of the joint of the longitudinal and cross members.

6. The intelligent design method for a thick-plate joint of longitudinal and cross members of an aluminum alloy vehicle frame according to claim 5, wherein an exponential linear unit (ELU) activation function is used as a neuron for the hidden layers of the neural network model, a stochastic gradient descent method is used as an optimizer, and a mean square error function is used as a loss function.

7. The intelligent design method for a thick-plate joint of longitudinal and cross members of an aluminum alloy vehicle frame according to claim 1, wherein in step S7, the forward optimization model is expressed as:
$$\begin{matrix}find DV = {( d , {t}_{1} , {t}_{2} , e , s , n , m )}^{T} \\ \{ \begin{matrix}min \{ Q ( x ) \} \\ s . t . \{ \begin{matrix}S \leq {S}_{y} \\ K \geq {K}_{0} \\ e \geq {e}_{0} \\ s \geq {s}_{0}\end{matrix}\end{matrix}\end{matrix}$$
wherein find DV=(d,t₁,t₂,e,s,n,m)^{T} represents optimal design variables to be obtained, and max{N(x)}&min{M(x)} represents an optimization objective of maximizing the fatigue life N and minimizing the mass M, with constraint conditions comprising: a maximum stress S of a connection joint of longitudinal and cross members being no greater than an allowable stress S_{y} for a material, rigidity K being no less than a set minimum rigidity value K₀, the edge distance e of fasteners being no less than a minimum edge distance e₀, and the spacing s being no less than a minimum spacing s₀.

8. The intelligent design method for a thick-plate joint of longitudinal and cross members of an aluminum alloy vehicle frame according to claim 1, wherein in step S7, the inverse optimization model is expressed as:
$$\begin{matrix}find DV = {( d , {t}_{1} , {t}_{2} , e , s , n , m )}^{T} \\ \{ \begin{matrix}min \{ Q ( x ) \} \\ s . t . \{ \begin{matrix}S \leq {S}_{y} \\ K \geq {K}_{0} \\ e \geq {e}_{0} \\ s \geq {s}_{0}\end{matrix}\end{matrix}\end{matrix}$$
wherein find DV=(d,t₁,t₂,e,s,n,m)^{T} represents optimal design variables to be obtained, Q(x) represents a difference between the target performance response variable and a performance response variable output by the neural network model, and min{Q(x)} represents an optimization objective of minimizing Q(x), with constraint conditions comprising: a maximum stress S of a connection joint of longitudinal and cross members being no greater than an allowable stress S_{y} for a material, rigidity K being no less than a set minimum rigidity value K₀, the edge distance e of fasteners being no less than a minimum edge distance e₀, and the spacing s being no less than a minimum spacing s₀.

9. An intelligent design device for a thick-plate joint of longitudinal and cross members of an aluminum alloy vehicle frame based on the intelligent design method according to claim 1, comprising:
an entire-vehicle finite element model establishment module configured to establish a finite element model of a vehicle frame;
a static performance analysis module configured to obtain strength and rigidity response information of the vehicle frame;
a fatigue performance analysis module configured to obtain a fatigue life of the vehicle frame;
a joint selection and finite element submodel establishment module configured to select a joint of longitudinal and cross members with the weakest static performance and fatigue performance of the vehicle frame and establish a joint finite element submodel;
a data set establishment module configured to obtain sample data using the joint finite element submodel and establish a joint design variable-performance response variable data set;
a neural network model training and utilization module configured to train a neural network model with the joint design variable-performance response variable data set established by the data set establishment module, the neural network model being configured to predict and output corresponding performance response variables based on input joint design variables;
a forward design module configured to output performance response variables corresponding to a plurality of joint design variable schemes using a trained neural network model, and select an optimal design scheme from the plurality of joint design variable schemes based on a forward optimization model; and
an inverse design module configured to output performance response variables corresponding to a plurality of joint design variable schemes using a trained neural network model, and select an optimal design scheme from the plurality of joint design variable schemes based on an inverse optimization model.

10. The intelligent design device according to claim 9, wherein in step S2, corresponding boundary conditions are applied under a bending condition and a torsion condition of the vehicle frame, and bending and torsion static performance of the vehicle frame is analyzed to obtain the strength and rigidity response information of the vehicle frame, wherein under the bending condition, translational degrees of freedom of a connection point of a rear suspension of the vehicle frame and the vehicle frame in a transverse direction, a longitudinal direction and a vertical direction are constrained, and a translational degree of freedom of a connection point of a front suspension and the vehicle frame in the vertical direction is constrained; and under the torsion condition, all translational and rotational degrees of freedom of connection points of the front and rear suspensions and the vehicle frame on a single side are constrained.

11. The intelligent design device according to claim 9, wherein in step S3, a load time history of a connection point of the vehicle frame and an assembly under typical conditions is extracted using the virtual prototype model of the entire vehicle, a vehicle frame load spectrum is compiled by a rain flow counting method, and the fatigue life of the vehicle frame is calculated by a nominal stress method and a cumulative fatigue damage theory.

12. The intelligent design device according to claim 9, wherein in step S5, suitable initial values and value ranges are set for the design variables in accordance with an actual connection of the longitudinal and cross members, and then a design variable test space is established using an optimal Latin hypercube sampling method to obtain a plurality of sets of sample data for establishing a data set.

13. The intelligent design device according to claim 9, wherein in step S6, the neural network model is a real-valued non-volume preserving (Real NVP) neural network model comprising an input layer, an output layer, and a plurality of hidden layers between the input layer and the output layer, each comprising a plurality of processing units correlated to one another; the input layer is configured to input design variables of the joint of the longitudinal and cross members, and the output layer is configured to output corresponding performance response variables of the joint of the longitudinal and cross members.

14. The intelligent design device according to claim 13, wherein an exponential linear unit (ELU) activation function is used as a neuron for the hidden layers of the neural network model, a stochastic gradient descent method is used as an optimizer, and a mean square error function is used as a loss function.

15. The intelligent design device according to claim 9, wherein in step S7, the forward optimization model is expressed as:
$$\begin{matrix}find DV = {( d , {t}_{1} , {t}_{2} , e , s , n , m )}^{T} \\ \{ \begin{matrix}min \{ Q ( x ) \} \\ s . t . \{ \begin{matrix}S \leq {S}_{y} \\ K \geq {K}_{0} \\ e \geq {e}_{0} \\ s \geq {s}_{0}\end{matrix}\end{matrix}\end{matrix}$$
wherein find DV=(d,t₁,t₂,e,s,n,m)^{T} represents optimal design variables to be obtained, and max{N(x)}&min{M(x)} represents an optimization objective of maximizing the fatigue life N and minimizing the mass M, with constraint conditions comprising: a maximum stress S of a connection joint of longitudinal and cross members being no greater than an allowable stress S_{y} for a material, rigidity K being no less than a set minimum rigidity value K₀, the edge distance e of fasteners being no less than a minimum edge distance e₀, and the spacing s being no less than a minimum spacing s₀.

16. The intelligent design device according to claim 9, wherein in step S7, the inverse optimization model is expressed as:
$$\begin{matrix}find DV = {( d , {t}_{1} , {t}_{2} , e , s , n , m )}^{T} \\ \{ \begin{matrix}min \{ Q ( x ) \} \\ s . t . \{ \begin{matrix}S \leq {S}_{y} \\ K \geq {K}_{0} \\ e \geq {e}_{0} \\ s \geq {s}_{0}\end{matrix}\end{matrix}\end{matrix}$$
wherein find DV=(d,t₁,t₂,e,s,n,m)^{T} represents optimal design variables to be obtained, Q(x) represents a difference between the target performance response variable and a performance response variable output by the neural network model, and min{Q(x)} represents an optimization objective of minimizing Q(x), with constraint conditions comprising: a maximum stress S of a connection joint of longitudinal and cross members being no greater than an allowable stress S_{y} for a material, rigidity K being no less than a set minimum rigidity value K₀, the edge distance e of fasteners being no less than a minimum edge distance e₀, and the spacing s being no less than a minimum spacing s₀.
